(19) United States
(12) Patent Application Publication
(10) Pub. No.: US 2006/0131555 A1
(43) Pub. Date: Jun. 22, 2006

(54) Resistance variable devices with controllable channels

(75) Inventors: Jun Liu, Boise, ID (US); Terry L. Gilton, Boise, ID (US); John T. Moore, Boise, ID (US); Kristy A. Campbell, Boise, ID (US)

Correspondence Address: DICKSTEIN SHAPIRO MORIN & OSHINSKY LLP, 2101 L Street, NW, Washington, DC, 20037, US

(73) Assignee: MICRON TECHNOLOGY, INC.

(21) Appl. No.: 11/018,370

(22) Filed: Dec. 22, 2004

(51) Int. Cl. H01L 29/04

(52) U.S. Cl. 257/3

(57) ABSTRACT

A memory element having a first electrode is provided, wherein the first electrode comprises at least one conductive nanostructure. The memory element further includes a second electrode and a resistance variable material layer between the first and second electrodes. The first electrode electrically is coupled to the resistance variable material. Methods for forming the memory element are also provided.

### FIELD OF THE INVENTION

The invention relates to the field of random access memory (RAM) devices formed using a resistance variable material, and in particular to an improved structure for and a method of manufacturing a resistance variable memory element.

### BACKGROUND OF THE INVENTION

Resistance variable memory elements, which include Programmable Conductive Random Access Memory (PCRAM) elements, have been investigated for suitability as semi-volatile and non-volatile random access memory devices. An exemplary PCRAM device is disclosed in U.S. Pat. No. 6,348,365 to Moore and Gilton.

In a PCRAM device, a conductive material, e.g., silver or other conductive ion, is incorporated into a chalcogenide glass. The resistance of the chalcogenide glass can be programmed to stable higher resistance and lower resistance states based on a voltage controlled movement of the conductive material within or into and out of the chalcogenide glass. An unprogrammed PCRAM device is normally in a higher resistance state. A write operation programs the PCRAM device to a lower resistance state by applying a voltage potential across the chalcogenide glass and forming a conduction channel. The PCRAM device may then be read by applying a voltage pulse of a lesser magnitude than required to program it; the resistance across the memory device is then sensed as higher or lower to define binary logic states.

The programmed lower resistance state of a PCRAM device can remain intact for an indefinite period, typically ranging from hours to weeks, after the voltage potentials are removed; however, some refreshing may be useful. The PCRAM device can be returned to its higher resistance state by applying a reverse voltage potential of about the same order of magnitude as used to write the device to the lower resistance state. Again, the higher resistance state is maintained in a semi- or non-volatile manner once the voltage potential is removed. In this way, such a device can function as a variable resistance memory having at least two resistance states, which can define two respective logic states, i.e., at least a bit of data.

A typical resistance variable cell 100 is shown in FIG. 1. The chalcogenide glass layer 7 is formed between top and bottom electrodes 2, 4 respectively. There may also be a metal containing layer 5, e.g., a silver layer, between the chalcogenide glass layer 7 and the top electrode 2. The metal layer 5 provides metal ions for the switching operations, and the electrode 2 may also provide metal ions for switching. In the conventional cell 100, the bottom electrode 4 may be formed as a plug within a dielectric layer 3. Typically, the electrode 4 is formed by chemical vapor deposition (CVD) processes. The conventional electrode 4 has some disadvantages. CVD processes result in seams or gaps between the electrode and adjacent structures. Additionally, the CVD processes produce electrodes with rough surfaces. Also, the plug electrode 4 has a relatively large surface area. These disadvantages can diminish the consistency and controllability of a device containing the conventional cell 100.

Therefore, it is desired to have an improved electrode for use in a resistance variable device and a method for forming the same.

### BRIEF SUMMARY OF THE INVENTION

Embodiments of the invention provide a memory element having a first electrode, wherein the first electrode comprises conductive nanostructures. The memory element further includes a second electrode and a resistance variable material layer between the first and second electrodes. The first electrode is electrically coupled to the resistance variable material. Embodiments of the invention also include methods for forming the memory element.

### BRIEF DESCRIPTION OF THE DRAWINGS

These and other features and advantages of the invention will be better understood from the following detailed description, which is provided in connection with the accompanying drawings.

FIG. 1 is a cross-sectional view of a conventional resistance variable memory element;

FIG. 2 is a cross-sectional diagram of a memory element according to an exemplary embodiment of the invention;

FIGS. 3A-3E depict the fabrication of the memory element of FIG. 2 at various stages of processing in accordance with an embodiment of the invention; and

FIG. 4 is a block diagram of a processor-based system having a memory device incorporating an element formed according to the invention.

### DETAILED DESCRIPTION OF THE INVENTION

In the following detailed description, reference is made to various specific embodiments of the invention. These embodiments are described with sufficient detail to enable those skilled in the art to practice the invention. It is to be understood that other embodiments may be employed, and that various structural, logical and electrical changes may be made without departing from the spirit or scope of the invention.

The term “substrate” used in the following description may include any supporting structure including, but not limited to, a plastic or a semiconductor substrate that has an exposed substrate surface. A semiconductor substrate should be understood to include silicon, silicon-on-insulator (SOI), silicon-on-sapphire (SOS), doped and undoped semiconductors, epitaxial layers of silicon supported by a base semiconductor foundation, and other semiconductor material structures. When reference is made to a semiconductor substrate or wafer in the following description, previous process steps may have been utilized to form regions or junctions in or over the base semiconductor or foundation.

The term “silver” is intended to include not only elemental silver, but silver with other trace metals or in various alloyed combinations with other metals as known in the semiconductor industry, as long as such silver alloy is conductive, and as long as the physical and electrical properties of the silver remain unchanged.

The term “silver-selenide” is intended to include various species of silver-selenide, including some species, which have a slight excess or deficit of silver, for instance, Ag₂Se, Ag₂₊ₓSe, and Ag₂₋ₓSe.

The term “tin” is intended to include not only elemental tin, but tin with other trace metals or in various alloyed combinations with other metals as known in the semiconductor industry, as long as such tin alloy is conductive, and as long as the physical and electrical properties of the tin remain unchanged.

The term “tin-chalcogenide” is intended to include various alloys, compounds, and mixtures of tin and chalcogens (e.g., sulfur (S), selenium (Se), tellurium (Te), polonium (Po), and oxygen (O)), including some species which have a slight excess or deficit of tin. For example, tin selenide, a species of tin-chalcogenide, may be represented by the general formula Sn_{1±x}Se. Though not being limited by a particular stoichiometric ratio between Sn and Se, devices of the present invention typically comprise an Sn_{1±x}Se species where x ranges between about 1 and about 0.

The term “chalcogenide glass” is intended to include glasses that comprise an element from group VIA (or group 16) of the periodic table. Group VIA elements, also referred to as chalcogens, include sulfur (S), selenium (Se), tellurium (Te), polonium (Po), and oxygen (O).

The term “semi-volatile memory” is intended to include any memory device or element which is capable of maintaining its memory state after power is removed from the device for a prolonged period of time. Thus, semi-volatile memory devices are capable of retaining stored data after the power source is disconnected or removed. Accordingly, the term “semi-volatile memory” is also intended to include not only semi-volatile memory devices, but also non-volatile memory devices.

The term “resistance variable material” is intended to include materials that can support the formation of a conduction channel in response to an applied voltage. Such materials include, for example, chalcogenide glasses, chalcogenide glasses comprising a metal, such as silver; a polymer, such as polymethylphenylacetylene, copperphtalocyanine, polyparaphenylene, polyphenylenevinylene, polyaniline, polythiophene and polypyrrole; and amorphous carbon. For instance, the term “resistance variable material” includes silver doped chalcogenide glasses, silver-germanium-selenide glasses, and chalcogenide glass comprising a silver-selenide layer.

The term “resistance variable memory element” is intended to include any memory element, including programmable conductor memory elements, semi-volatile memory elements, and non-volatile memory elements, which exhibit a resistance change in response to an applied voltage.

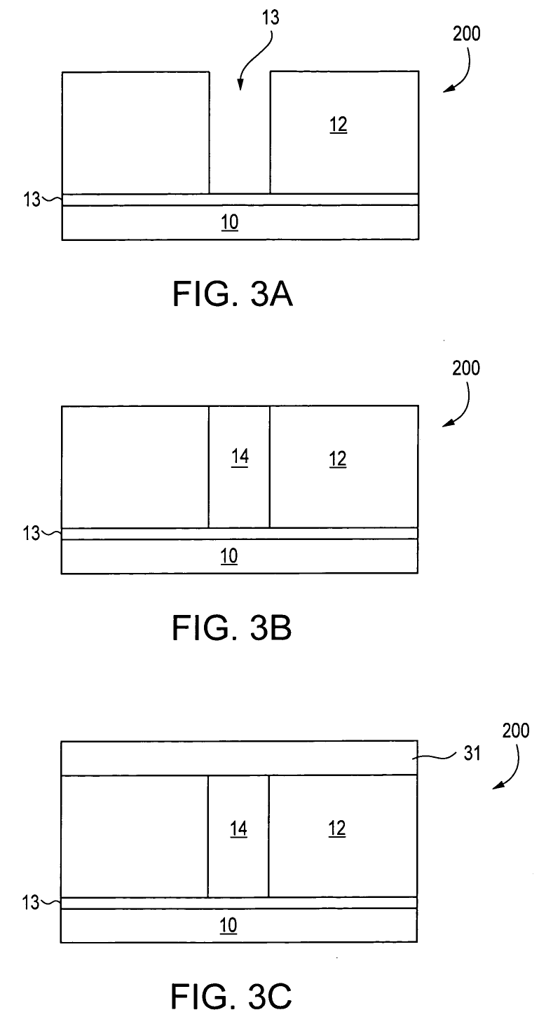

The invention is now explained with reference to the figures, which illustrate exemplary embodiments and where like reference numbers indicate like features. FIG. 2 depicts a memory element 200 according to an exemplary embodiment of the invention. The memory element 200 is formed on a substrate 10. Over the substrate 10, though not necessarily directly so, is a conductive address line 13, which serves as an interconnect for the device 200 shown and a plurality of other similar devices of a portion of a memory array of which the shown device 200 is a part. It is possible to incorporate an optional insulating layer (not shown) between the substrate 10 and address line 13, and this may be preferred if the substrate 10 is semiconductor-based.

Over the address line 13 is a conductive plug 14, which is defined within an insulating layer 12, which is also over the address line 13. The conductive plug 14 is formed within a first insulating layer 12. Over the conductive plug 14 and first insulating layer 12 are conductive nanostructures 33. Nanostructures are structures having a dimension on the order of nanometers or smaller. Examples of nanostructures include nanotubes, such as carbon nanotubes, which are tubular carbon molecules having diameters on the order of nanometers, e.g., as small as about 10 nanometers (nm) or smaller; and nanowires.

In the illustrated example, the conductive nanostructures 33 are located within an anodic aluminum oxide layer 31. For example, the aluminum oxide layer 31 can contain conductive nanowires or nanotubes, which are the conductive nanostructures 33. The nanostructures 33 serve as a first electrode and are positioned within the layer 31 to electrically couple the plug 14 to a stack 11 of layers, which includes at least one resistance variable material. The illustrated nanowires or nanotubes (i.e., nanostructures 33) are vertically positioned in the layer 31. One or more nanostructures 33 are in contact with the conductive plug 14. Preferably, one or two nanostructures 33 are in contact with the conductive plug 14. The nanostructures 33 serve as a first electrode.

A stack of layers 11, which includes at least one layer of resistance variable material is provided over the anodic aluminum oxide layer 31 and nanostructures 33. In the exemplary embodiment of FIG. 2, the stack of layers 11 includes a first chalcogenide glass layer 17, a metal containing layer 18, a first metal layer 28, a second chalcogenide glass layer 20, a second metal layer 29 and a conductive adhesion layer 27. The first chalcogenide glass layer 17 is electrically coupled to the nanostructures 33. A second electrode 22 is over the stack 11.

The invention is not limited to a stack 11, having specific layers 17, 18, 28, 20, 29, 27. Embodiments of the invention include stacks 11 having greater than or fewer than six layers and having layers comprising different materials providing that at least one layer is a resistance variable material. For example, any one or more of the glass layers 17, 20 can be made up of a plurality of sublayers.

Preferably, the first chalcogenide glass layer 17 is germanium-selenide glass having a GeₓSe₁₀₀₋ₓ stoichiometry. The preferred stoichiometric range is between about Ge₂₀Se₈₀ to about Ge₄₃Se₅₇, and is more preferably about Ge₄₀Se₆₀. The metal containing layer 18 may be any suitable metal containing layer, for instance, silver-chalcogenide layers, such as silver-sulfide, silver-oxide, silver-telluride, and silver-selenide; among others. The second glass layer 20 can be a second chalcogenide glass layer formed of a same material as the first chalcogenide glass layer 17.

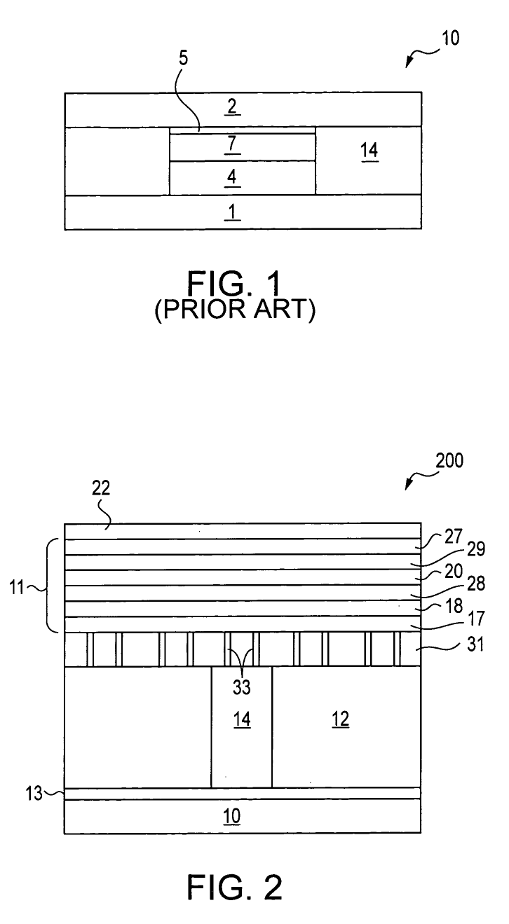

By using nanostructures 33 as the first electrode, the surface area of the first electrode in contact with the first chalcogenide glass layer 17 is minimized as compared to the surface area of the conventional electrode 4 in contact with the chalcogenide glass layer 7 in the conventional memory element 10 (FIG. 1). Use of the nanostructures 33 promotes consistency and controllability of the memory element 200. During operation, the nanostructures 33 also serve to enhance the electric field to facilitate the formation of a conduction channel by ionic movement to improve the switching of the memory element 200. Also, since the nanostructures 33 are smaller than the electrode 4 in a conventional memory element 10 (FIG. 1), there can be better control over the particular location where the conduction channel will be formed. Accordingly, the nanostructures 33 serve to improve the uniformity of the switching properties of the memory element 200.

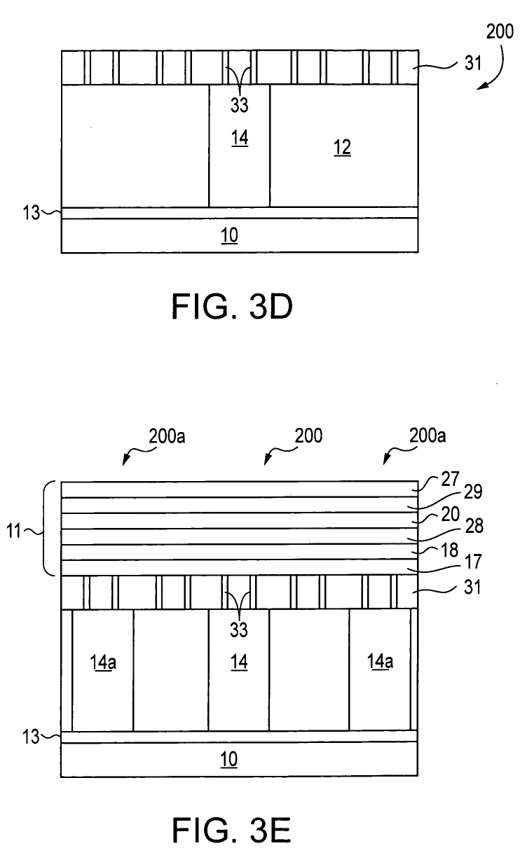

FIGS. 3A-3F depict the formation of the memory element 200 according to an exemplary embodiment of the invention. No particular order is required for any of the actions described herein, except for those logically requiring the results of prior actions. Accordingly, while the actions below are described as being performed in a general order, the order is exemplary only and can be altered if desired.

FIG. 3A illustrates a conductive address line 13, formed over the substrate 10. Optionally, an insulating layer (not shown) can be formed between the substrate 10 and address line 13, and this may be preferred if the substrate 10 is semiconductor-based. The conductive address line 13 can be formed by any suitable techniques and can be any material known in the art as being useful for providing an interconnect line, such as doped polysilicon, silver (Ag), gold (Au), copper (Cu), tungsten (W), nickel (Ni), aluminum (Al), platinum (Pt), titanium (Ti), and other materials.

A first insulating layer 12 is formed over the conductive address line 13. The insulating layer 12 may be formed by any known deposition methods, such as sputtering by chemical vapor deposition (CVD), plasma enhanced CVD (PECVD) or physical vapor deposition (PVD). The insulating layer 12 may be formed of a conventional insulating oxide, such as silicon oxide (SiO₂), a silicon nitride (Si₃N₄); a low dielectric constant material; among many others.

An opening 13 extending to the conductive address line 13 is formed in the first insulating layer 12. The opening 13 may be formed by known methods in the art, for example, by a conventional patterning and etching process.

FIG. 3B depicts the formation of the conductive plug 14. A conductive material is deposited through the opening 13 to form the plug 14 such that it is electrically coupled to the conductive address line 13. Preferably, the plug 14 is a metal plug. A chemical mechanical polish (CMP) step is conducted to planarize the metal plug 14 and insulating layer 12. The metal plug 14 may comprise any conductive material, for example, tungsten, nickel, tantalum, aluminum, platinum, conductive nitrides, and other materials.

As shown in FIG. 3C, an anodic aluminum oxide layer 31 is formed over the metal plug and the insulating layer 12. The anodic aluminum oxide layer 13 serves as a template layer for forming the nanostructures 33 (FIG. 2). Layer 31 can be formed by known techniques having regularly spaced nanopores (not shown), such that one or more nanopores are located over the metal plug 14. Preferably, the layer 31 is formed such that about 1 or 2 nanopores are located over the metal plug 14.

FIG. 3D illustrates the formation of the conductive nanostructures 33 within the nanopores of the anodic aluminum oxide layer 31. The nanostructures 33 can be formed by any suitable process, such as, electrodeposition, among others. The nanostructures 33 may be carbon nanotubes or may comprise any conductive material, for example, tungsten, nickel, tantalum, aluminum, platinum, conductive nitrides, and other materials. Accordingly, the nanostructures may be a same material as the conductive plug 14.

Techniques for forming nanostructures, e.g., nanotubes and/or nanowires, are described, for example, in U.S. Pat. Nos. 6,325,909; 6,538,367; 6,548,313; 6,515,325; 6,566,665; and 6,566,704, which are incorporated herein by reference.

By forming the first electrode as nanostructures 33 (e.g., nanotubes or nanowires), the seams or gaps that occur when an electrode is formed in the conventional chemical vapor deposition plug process can be avoided. Additionally, the drawbacks created by the rough surfaces of the conventional chemical vapor deposition (CVD) deposited plug electrode 4 (FIG. 1) can be avoided. Additionally, the conventional CVD plug processes limit the materials that can be used as the electrode 4, whereas processes for forming nanostructures 33 are available for a wider range of suitable materials.

Referring to FIG. 3E, the stack 11 of layers for producing resistance variable memory elements is formed over the anodic aluminum oxide layer 31 and nanostructures 33. The element 200 is defined by the location of the plug 14. As shown in FIG. 3E, additional plugs 14a can be formed in a similar manner as plug 14 to define additional memory elements 200a.

As an example, a first chalcogenide glass layer 17 is formed over layer 31. According to an embodiment of the invention, the first chalcogenide glass layer 17 can be germanium-selenide glass having a GeₓSe₁₀₀₋ₓ stoichiometry. The preferred stoichiometric range is between about Ge₂₀Se₈₀ to about Ge₄₃Se₅₇ and is more preferably about Ge₄₀Se₆₀. The first chalcogenide glass layer 17 preferably has a thickness from about 100 Angstroms (Å) to about 1000 Å and is more preferably about 150 Å.

The formation of the first chalcogenide glass layer 17, having a stoichiometric composition in accordance with the invention, may be accomplished by any suitable method. For instance, germanium-selenide glass can be formed by evaporation, co-sputtering germanium and selenium in the appropriate ratios, sputtering using a germanium-selenide target having the desired stoichiometry, or chemical vapor deposition with stoichiometric amounts of GeH₄ and SeH₂ gases (or various compositions of these gases), which result in a germanium-selenide film of the desired stoichiometry, are examples of methods which may be used.

A metal containing layer 18 is formed over the first chalcogenide glass layer 17. The metal containing layer 18 may be any suitable metal containing layer. For instance, suitable metal containing layers include silver-chalcogenide layers, such as silver-sulfide, silver-oxide, silver-telluride, and silver-selenide. Alternatively, the metal containing layer 18 is a layer of tin-chalcogenide, preferably tin selenide (Sn_{1±x}Se, where x is between about 1 and 0). It is also possible that other chalcogenide materials may be substituted for selenium here, such as sulfur, oxygen, or tellurium.

A variety of processes can be used to form the metal containing layer 18. For instance, physical vapor deposition techniques such as evaporative deposition, sputtering may be used, chemical vapor deposition, or co-evaporation may be used. Also, where the metal containing layer 18 is silver-selenide, depositing a layer of selenium above a layer of silver to form a silver-selenide layer can also be used.

The metal containing layer 18 is preferably about 500 Å thick; however, its thickness depends, in part, on the thickness of the underlying chalcogenide glass layer 17. Preferably, the thickness of layers 17 and 18 is such that a ratio of the metal containing layer 18 thickness to the first chalcogenide glass layer 17 thicknesses is between about 5:1 and about 1:1. In other words, the metal containing layer 18 thickness is between about 1 to about 5 times greater than the first chalcogenide glass layer 17 thickness. Even more preferably, the ratio is about 2.5:1.

Still referring to FIG. 3E, a metal layer 28 is provided over the metal containing layer 18, with silver (Ag) being preferred as the metal. This metal layer 28 should be about 500 Å thick. This silver (or other metal) layer 28 assists the switching operation of the memory device.

A second chalcogenide glass layer 20 is formed over the first metal layer 28. The second chalcogenide glass layer 20 may, but need not, have the same stoichiometric composition as the first chalcogenide glass layer, e.g., GeₓSe₁₀₀₋ₓ. Thus, the second glass layer 20 may be of a different material, different stoichiometry, and/or more rigid than the first chalcogenide glass layer 17.

The second chalcogenide glass layer 20 thickness is preferably between about 100 Å to about 100 Å, and is more preferably about 150 Å. The second chalcogenide glass layer 20 may be formed by any suitable method. For example, chemical vapor deposition, evaporation, co-sputtering, or sputtering using a target having the desired stoichiometry, may be used.

A second metal layer 29 is deposited over the second chalcogenide glass layer 20 by any suitable means, such as sputtering or plating techniques, including electroplating or electroless plating. The desired thickness of the second metal layer 29 is about 200 Å. The second metal layer 29 is also preferably a silver layer.

A conductive adhesion layer 27 is formed over the second silver layer 29. Suitable materials for the conductive adhesion layer 27 include conductive materials capable of providing good adhesion between the second silver layer 29 and the top electrode layer 22. Desirable materials for the conductive adhesion layer 27 include chalcogenide glasses. Therefore, the conductive adhesion layer 27 can be a third chalcogenide glass layer and can be a same material as the first and/or second chalcogenide glass layers 17, 20.

A second electrode 22 is formed over the conductive adhesion layer 27 to achieve the structure shown in FIG. 2. The second electrode 22 may comprise any electrically conductive material, for example, tungsten, tantalum, titanium, conductive nitrides, or other materials.

Conventional processing steps can be carried out to electrically couple the resistance variable memory element 200 to various circuits of a memory array.

After formation of the memory element 200, a conditioning step is conducted to form a conduction channel within the first chalcogenide glass layer 17. Specifically, in the illustrated embodiment of FIG. 2, the conditioning step comprises applying a potential across the memory element structure 200 such that metal ions from the metal containing layer 18 are driven into the first chalcogenide glass layers 17, forming a conduction channel. After conditioning, movement of metal ions into or out of the conduction channel by application of voltages across the memory element structure 200 causes an overall resistance change for the memory element 200. The pulse width and amplitude of the conditioning potential generally has a longer pulse width and higher amplitude than a typical potential used to program the memory element. After the conditioning step, the memory element 200 may be programmed.

The embodiments described above refer to the formation of only a few possible resistance variable memory element structures (e.g., PCRAM) in accordance with the invention, which may be part of a memory array. It must be understood, however, that the invention contemplates the formation of other memory structures within the spirit of the invention, which can be fabricated as a memory array and operated with memory element access circuits.

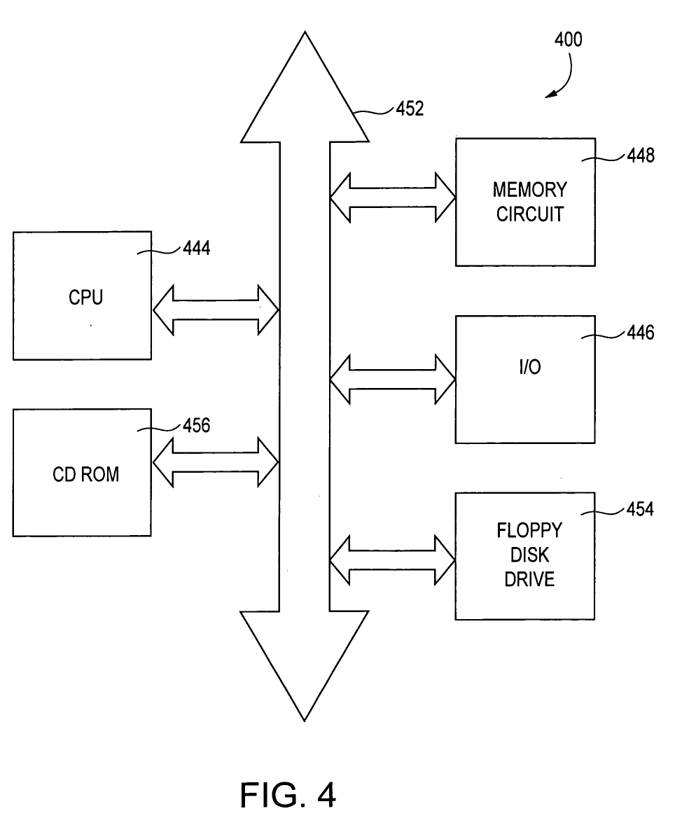

FIG. 4 illustrates a processor system 400 that includes a memory circuit 448, e.g., a memory device, which employs resistance variable memory elements (e.g., element 200 (FIG. 2)) according to the invention. The processor system 400, which can be, for example, a computer system, generally comprises a central processing unit (CPU) 444, such as a microprocessor, a digital signal processor, or other programmable digital logic devices, which communicates with an input/output (I/O) device 446 over a bus 452. The memory circuit 448 communicates with the CPU 444 over bus 452 typically through a memory controller.

In the case of a computer system, the processor system 400 may include peripheral devices such as a floppy disk drive 454 and a compact disc (CD) ROM drive 456, which also communicate with CPU 444 over the bus 452. Memory circuit 448 is preferably constructed as an integrated circuit, which includes one or more resistance variable memory elements, e.g., elements 200 (FIG. 2). If desired, the memory circuit 448 may be combined with the processor, for example CPU 444, in a single integrated circuit.

The above description and drawings are only to be considered illustrative of exemplary embodiments, which achieve the features and advantages of the present invention. Modification and substitutions to specific process conditions and structures can be made without departing from the spirit and scope of the present invention. Accordingly, the invention is not to be considered as being limited by the foregoing description and drawings, but is only limited by the scope of the appended claims.

What is claimed as new and desired to be protected by Letters Patent of the United States is:

1. A memory element comprising:
a first electrode, the first electrode comprising at least one conductive nanostructure;
a second electrode; and
a resistance variable material layer between the first and second electrodes, the first electrode being electrically coupled to the resistance variable material.

2. The memory element of claim 1, wherein the first electrode comprises at least one nanowire.

3. The memory element of claim 1, wherein the first electrode comprises at least one nanotube.

4. The memory element of claim 1, further comprising an anodic aluminum oxide layer, wherein the at least one nanostructure is within the anodic aluminum oxide layer.

5. The memory element of claim 1, wherein the first electrode comprises a plurality of nanostructures.

6. The memory element of claim 5, wherein the first electrode comprises two nanostructures.

7. The memory element of claim 5, wherein the first electrode comprises two nanotubes.

8. The memory element of claim 5, wherein the first electrode comprises two nanowires.

9. The memory element of claim 1, wherein the resistance variable material comprises chalcogenide glass.

10. The memory element of claim 9, wherein the chalcogenide glass has a formula GeₓSe₁₀₀₋ₓ, where x=a positive integer.

11. The memory element of claim 1, wherein the resistance variable material comprises amorphous carbon.

12. The memory element of claim 1, further comprising a conductive plug, the first electrode being electrically coupled to the conductive plug.

13. The memory element of claim 1, further comprising:
a first chalcogenide glass layer over the first electrode;
a first metal layer over the first chalcogenide glass layer; and
a metal containing layer over the first metal layer.

14. The memory element of claim 13, wherein the metal containing layer comprises silver.

15. The memory element of claim 13, wherein the metal containing layer comprises tin.

16. The memory element of claim 13, wherein the first metal layer comprises a silver layer.

17. The memory element of claim 13, further comprising:
a second chalcogenide glass layer over the metal containing layer;
a second metal layer over the second chalcogenide glass layer; and
a conductive adhesion layer over the second metal layer.

18. The memory element of claim 17, wherein the conductive adhesion layer is a glass layer.

19. A memory element comprising:
a substrate;
a conductive line over the substrate;
a metal plug electrically coupled to the conductive line;
an anodic aluminum oxide layer over the metal plug;
a plurality of conductive nanostructures within the anodic aluminum oxide layer;
at least one nanostructure being electrically coupled to the metal plug;
at least one resistance variable material layer is over the anodic aluminum oxide layer; and
an electrode over the at least one resistance variable material layer.

20. The memory element of claim 19, wherein the at least one resistance variable material layer is at least one layer within a stack of layers between the at least one nanostructure and the electrode.

21. The memory element of claim 20, wherein the stack of layers comprises a metal containing layer.

22. The memory element of claim 21, wherein the metal containing layer comprises silver.

23. The memory element of claim 21, wherein the metal containing layer comprises tin.

24. A processor system, comprising:
a processor; and
a memory device comprising a memory element, the memory element comprising a metal plug over a substrate; an anodic aluminum oxide layer over the metal plug; a plurality of conductive nanostructures within the anodic aluminum oxide layer; at least one nanostructure being electrically coupled to the metal plug; at least one resistance variable material layer is over the anodic aluminum oxide layer; and a second electrode over the at least one resistance variable material layer.

25. The system of claim 24, wherein two nanotubes are electrically coupled to the metal plug.

26. The system of claim 24, wherein two nanowires are electrically coupled to the metal plug.

27. A processor system, comprising:
a processor; and
a memory device comprising a memory element, the memory element comprising a first electrode, the first electrode comprising conductive nanostructures, a second electrode and a resistance variable material layer between the first and second electrodes, the first electrode electrically coupled to the resistance variable material.

28. The system of claim 27, wherein the first electrode comprises at least one nanowire.

29. The system of claim 27, wherein the first electrode comprises at least one nanotube.

30. The system of claim 27, wherein the first electrode comprises a plurality of nanostructures.

31. The system of claim 27, wherein the resistance variable material comprises chalcogenide glass.

32. The system of claim 27, wherein the resistance variable material comprises amorphous carbon.

33. A method of forming a memory element, the method comprising the acts of:
forming a first electrode comprising at least one conductive nanostructure;
forming a second electrode; and
forming a resistance variable material layer between the first and second electrodes, the first electrode formed electrically coupled to the resistance variable material.

34. The method of claim 33, wherein forming the first electrode comprises forming at least one nanotube.

35. The method of claim 33, wherein forming the first electrode comprises forming at least one nanowire.

36. The method of claim 33, further comprising the act of forming an anodic aluminum oxide layer, wherein forming the first electrode comprises forming the at least one nanostructure within the anodic aluminum oxide layer.

37. The method of claim 33, wherein forming the first electrode comprises forming a plurality of nanostructures.

38. The method of claim 37, wherein forming the first electrode comprises forming two nanostructures.

39. The method of claim 33, wherein forming the resistance variable material layer comprises forming a chalcogenide glass layer.

40. The method of claim 33, wherein forming the resistance variable material layer comprises forming an amorphous carbon layer.

41. The method of claim 33, further comprising the acts of:
forming a first chalcogenide glass layer over the first electrode;
forming a first metal layer over the first chalcogenide glass layer; and
forming a metal containing layer over the first metal layer.

42. The method of claim 41, wherein forming the metal containing layer comprises forming a silver containing layer.

43. The method of claim 41, wherein forming the metal containing layer comprises forming a tin containing layer.

44. The method of claim 41, wherein forming the first metal layer comprises forming a silver layer.

45. The method of claim 41, further comprising the acts of:
forming a second chalcogenide glass layer over the metal containing layer;
forming a second metal layer over the second chalcogenide glass layer; and
forming a conductive adhesion layer over the second metal layer.

46. The method of claim 45, wherein forming the conductive adhesion layer comprises forming a glass layer.

47. A method of forming a memory element, the method comprising the acts of:
providing a substrate;
forming a conductive line over the substrate;
forming an insulating layer over the substrate;
forming a metal plug within the insulating layer and electrically coupled to the conductive line;
forming an anodic aluminum oxide layer over the metal plug;
forming a plurality of conductive nanotubes within the anodic aluminum oxide layer such that at least one nanotube is electrically coupled to the metal plug;
forming at least one resistance variable material layer over the anodic aluminum oxide layer; and
forming a second electrode over the at least one resistance variable material layer.

48. The method of claim 47, wherein forming the plurality of conductive nanotubes comprises forming two nanotubes electrically coupled to the metal plug.

49. The method of claim 47, further comprising the step of forming a stack of layers between the at least one nanostructure and the electrode, wherein forming the at least one resistance variable material layer comprises forming the at least one resistance variable material layer as a layer within the stack.

50. The method of claim 49, wherein forming the stack of layers comprises forming a metal containing layer.

51. The method of claim 50, wherein forming the metal containing layer comprises forming a silver containing layer.

52. The method of claim 50, wherein forming the metal containing layer comprises forming a tin containing layer.

53. A method of forming a memory element, the method comprising the acts of:
providing a substrate;
forming a conductive line over the substrate;
forming an insulating layer over the substrate;
forming a metal plug within the insulating layer and electrically coupled to the conductive line;
forming an anodic aluminum oxide layer over the metal plug;
forming a plurality of conductive nanowires within the anodic aluminum oxide layer such that at least one nanowire is electrically coupled to the metal plug;
forming at least one resistance variable material layer over the anodic aluminum oxide layer; and
forming a second electrode over the at least one resistance variable material layer.

54. The method of claim 53, wherein forming the plurality of conductive nanowires comprises forming two nanowires electrically coupled to the metal plug.

55. The method of claim 53, further comprising the step of forming a stack of layers between the at least one nanostructure and the electrode, wherein forming the at least one resistance variable material layer comprises forming the at least one resistance variable material layer as a layer within the stack.

56. The method of claim 55, wherein forming the stack of layers comprises forming a metal containing layer.

57. The method of claim 56, wherein forming the metal containing layer comprises forming a silver containing layer.

58. The method of claim 56, wherein forming the metal containing layer comprises forming a tin containing layer.
